(19) United States
(12) Patent Application Publication
(10) Pub. No.: US 2026/0237599 A1
(43) Pub. Date: Aug. 13, 2026

(54) METHOD OF CONFIGURING A CHARGED PARTICLE BEAM SYSTEM AND CHARGED PARTICLE BEAM SYSTEM

(71) Applicant: ICT Integrated Circuit Testing Gesellschaft für Halbleiterprüftechnik mbH, Heimstetten (DE)

(72) Inventors: Dominik Ehberger, Ebersberg (DE); Kathrin Juliane Mohler, Olching (DE); John Breuer, München (DE)

(73) Assignee: ICT Integrated Circuit Testing Gesellschaft für Halbleiterprüftechnik mbH, Heimstetten (DE)

(21) Appl. No.: 19/051,080

(22) Filed: Feb. 11, 2025

(51) Int. Cl. H01J 37/302

(52) U.S. Cl. CPC H01J 37/3023; H01J 2237/24578

(57) ABSTRACT

A method of configuring a charged particle beam system is provided. The method comprises providing an initial configuration matrix of the charged particle beam system, relating a plurality of charged particle beam system settings to respective configurations of one or more beam influencing elements, and providing a configuration matrix M from the initial configuration matrix; determining a correlation matrix C corresponding to the configuration matrix M, the correlation matrix C describing an influence of configurations of the one or more beam influencing elements on at least one beam spot parameter of a charged particle beam; replacing the configuration matrix M based upon the correlation matrix C; and iteratively repeating a diagonalization iteration of determining the correlation matrix C corresponding to the configuration matrix M, and replacing the configuration matrix M, until the correlation matrix C corresponding to the configuration matrix M fulfills a diagonalization criterium.

### TECHNICAL FIELD

Embodiments described herein relate to methods of configuring a charged particle beam system, particularly a scanning electron microscope (SEM). Specifically, a configuration matrix of the charged particle beam system can be improved. Embodiments further relate to methods of setting one or more beam influencing elements and to charged particle beam systems for at least one of inspecting or imaging a sample that is configured for any of the methods described herein.

### BACKGROUND

Modern semiconductor technology has created a high demand for structuring and probing specimens on a nanometer or even sub-nanometer scale. Micrometer and nanometer-scale process control, inspection or structuring is often carried out using charged particle beams, e.g. electron beams, which are generated, shaped, deflected and focused in charged particle beam systems, such as electron microscopes or electron beam pattern generators. For inspection purposes, charged particle beams offer a superior spatial resolution compared to, e.g., photon beams.

Inspection apparatuses using charged particle beams, such as scanning electron microscopes (SEM), have many functions in a plurality of industrial fields, including, but not limited to, inspection of electronic circuits, exposure systems for lithography, detecting systems, defect-inspection tools, and testing systems for integrated circuits. In particle beam systems, fine beam probes with a high current density can be used. For instance, in the case of an SEM, the primary electron beam generates signal particles such as secondary electrons (SE) and/or backscattered electrons (BSE) that can be used to image and/or inspect a sample.

In charged particle beam systems, parameters of the beam spot of the charged particle beam system can be influenced by one or more beam influencing elements. Charged particle beam system settings or excitations can be related to respective configurations of the one or more beam influencing elements.

In typical charged particle beam systems, cross-talk between different orders of beam spot parameters and the associated one or more beam influencing elements can occur, particularly due to misalignment or electrical and/or mechanical tolerances that lead to a coupling of various degrees of freedom in an alignment system. Thus, a high degree of coupling can be present between different alignments. A change of a charged particle beam setting influences not only a beam spot parameter theoretically associated with said charged particle beam setting, but can influence beam spot parameters of different orders. Optimizing interlinked parameters at the same time is difficult and time-consuming. Cross-talk phenomena may vary between different charged particle beam systems, such that general configuration strategies may be available only to a limited extent.

In view of the above, it would be beneficial to accurately, reliably, and reproducibly configure a charged particle beam system. In particular, a configuration of the charged particle system where each degree of freedom is linked to one and only one beam spot parameter without cross-talk would be beneficial.

### SUMMARY

In light of the above, a method of configuring a charged particle beam system, a method of setting one or more beam influencing elements, and a charged particle beam system are provided according to the independent claims.

According to an aspect, a method of configuring a charged particle beam system comprising one or more beam influencing elements is provided. The method includes providing an initial configuration matrix of the charged particle beam system, the initial configuration matrix relating a plurality of charged particle beam system settings to respective configurations of the one or more beam influencing elements, and providing a configuration matrix M from the initial configuration matrix; determining a correlation matrix C corresponding to the configuration matrix M of the charged particle beam system, the correlation matrix C describing an influence of configurations of the one or more beam influencing elements on at least one beam spot parameter of a charged particle beam of the charged particle beam system; replacing the configuration matrix M based upon the correlation matrix C; and iteratively repeating a diagonalization iteration of determining the correlation matrix C corresponding to the configuration matrix M, and replacing the configuration matrix M, until the correlation matrix C corresponding to the configuration matrix M fulfills a diagonalization criterium.

According to an aspect, a method of setting one or more beam influencing elements is provided. The method comprises receiving charged particle beam system settings; providing a configuration matrix M; and setting one or more beam influencing elements of a charged particle beam system according to the configuration matrix M and the charged particle beam system settings; wherein the configuration matrix M is configured to reduce crosstalk between different orders of charged particle beam system settings of the charged particle beam system.

According to an aspect, a charged particle beam system comprising one or more beam influencing elements and a controller is provided. The controller is configured to provide an initial configuration matrix of the charged particle beam system, the initial configuration matrix relating a plurality of charged particle beam system settings to respective configurations of the one or more beam influencing elements; and to provide a configuration matrix M from the initial configuration matrix; determine a correlation matrix C corresponding to the configuration matrix M of the charged particle beam system, the correlation matrix C describing an influence of configurations of the one or more beam influencing elements on at least one beam spot parameter of a charged particle beam of the charged particle beam system; replace the configuration matrix M based upon the correlation matrix C and iteratively repeat a diagonalization iteration of determining the correlation matrix C corresponding to the configuration matrix M, and replacing the configuration matrix M, until the correlation matrix C corresponding to the configuration matrix M fulfills a diagonalization criterium.

Embodiments are also directed at systems and apparatuses for carrying out the disclosed methods and include parts for performing the individual method actions. The described method may be performed by way of hardware parts, a computer programmed by appropriate software, by any combination of the two or in any other manner. Furthermore, embodiments are also directed at methods of operating the described systems and apparatuses.

Further advantages, features, aspects and details that can be combined with embodiments described herein are evident from the dependent claims, the description and the drawings.

### BRIEF DESCRIPTION OF THE DRAWINGS

So that the manner in which the above recited features of the present disclosure can be understood in detail, a more particular description, briefly summarized above, may be had by reference to embodiments. The accompanying drawings relate to one or more embodiments and are described in the following.

FIG. 1 shows a schematic view of a charged particle beam system according to embodiments described herein that is adapted for being operated according to any of the methods described herein;

FIG. 2 shows a schematic flow diagram illustrating a method of configuring a charged particle beam system according to embodiments described herein;

FIG. 3 shows a schematic flow diagram illustrating a method of setting one or more beam influencing elements according to embodiments described herein;

FIG. 4 schematically shows an order iteration according to embodiments described herein.

### DETAILED DESCRIPTION

Reference will now be made in detail to the various embodiments, one or more examples of which are illustrated in the figures. Within the following description of the drawings, same reference numbers refer to same components. Generally, only the differences with respect to individual embodiments are described. Each example is provided by way of explanation and is not meant as a limitation. Further, features illustrated or described as part of one embodiment can be used on or in conjunction with other embodiments to yield yet a further embodiment. It is intended that the description includes such modifications and variations.

Embodiments described herein relate to an improved alignment of charged particle beam systems. Particularly, a method for providing a charged particle beam system with decoupled degrees of freedom is provided, i.e. a system where each degree of freedom of alignment of the charged particle beam system is only linked to one charged particle beam observable is provided. To obtain a charged particle system with decoupled degrees of freedom, the configuration matrix of the charged particle beam system is diagonalized by a method according to embodiments described herein.

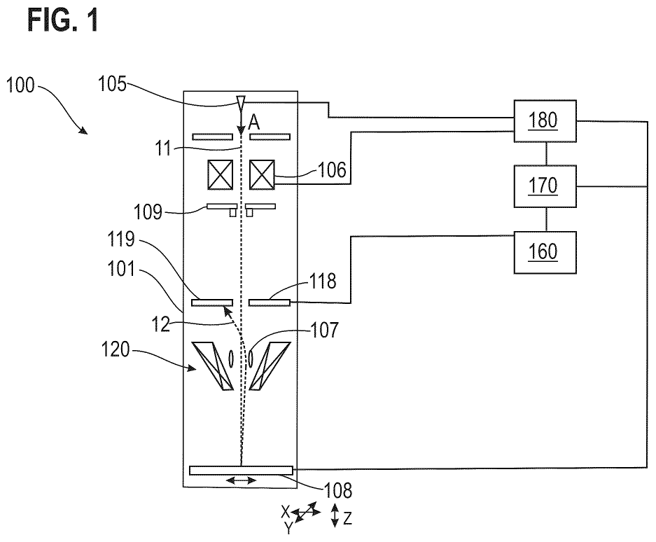

FIG. 1 is a schematic view of a charged particle beam system 100 for inspecting and/or imaging a sample according to embodiments described herein. The charged particle beam system 100 includes a charged particle source 105, particularly an electron source, for emitting a primary charged particle beam 11, particularly an electron beam. The primary charged particle beam 11 propagates along an optical axis A of the charged particle beam system 100. The charged particle beam system 100 further includes a sample stage 108 and a focusing lens 120. The focusing lens 120, particularly an objective lens, focuses the primary charged particle beam 11 on a sample at a sample position on the sample stage 108. The objective lens may particularly be a magnetic objective lens, an electrostatic magnetic lens, or a combined magnetic-electrostatic lens. The objective lens may optionally include a retarding field device, e.g. one or more retarding electrodes, configured to decelerate the charged particle beam to a predetermined landing energy on the sample.

The charged particle beam system 100 further includes charged particle detectors 118, 119, particularly electron detectors. The charged particle detectors 118, 119 may be configured to detect signal particles of a signal charged particle beam 12, in particular secondary electrons and/or backscattered electrons. The charged particle detectors 118, 119 may include multiple detectors 118, 119 or detector elements.

The beam-optical components of the charged particle beam system 100 are typically placed in a vacuum chamber 101 that can be evacuated. The primary charged particle beam 11 can typically propagate along the optical axis A from the charged particle source 105 toward the sample stage 108 and hit the sample at a sub-atmospheric pressure, e.g. a pressure below 10⁻³ mbar or a pressure below 10⁻⁵ mbar.

In some embodiments, a condenser lens system 109 may be arranged downstream of the charged particle source 105, particularly for collimating the primary charged particle beam 11 propagating toward the focusing lens 120. In some embodiments, the charged particle beam system may include one or more beam influencing elements 106 to influence the primary charged particle beam 11.

In some embodiments, the charged particle beam system 100 may be an electron microscope, particularly a scanning electron microscope. A scan deflector 107 may be provided for scanning the primary charged particle beam 11 over the sample at the sample position of the sample stage 108.

The sample stage 108 can be moved in at least one dimension, particularly in one dimension of the sample plane. The sample plane is substantially perpendicular to the optical axis A and is the plane in which a sample is positioned in the charged particle beam system 100 to be inspected. The sample stage 108 may exemplarily be moved in an x direction and/or in a y-direction. The sample stage 108 may be moved continuously or step-wise.

A detector signal receiving unit 160 may be provided for receiving one or more detector signals of the detectors 118, 119 of the charged particle beam system 100. The detector signal receiving unit 160 can forward the one or more detector signals of the detectors 118, 119 to a processing unit 170 that is configured to process the detector signals in accordance with the methods described herein. The processing unit 170 can communicate with the sample stage 108. In particular, the processing unit 170 can receive information on the position of the sample stage 108 and can determine the position of a sample. The processing unit 170 can associate a detector signal received by the detector signal receiving unit 160 from the detectors 118, 119, with the position of the sample stage 108.

A controller 180 may be provided for controlling the charged particle beam system 100. The controller 180 may communicate with at least one of the one or more beam influencing element 106 and/or the sample stage 108. The controller 180 may set a setting of the one or more beam influencing elements 106. Exemplarily, the controller 180 may set at least one of a current configuration or a voltage configuration of the one or more beam influencing element 106.

In some embodiments, the controller 180 may set a relative sample position of the sample by controlling the sample stage 108. The controller 180 may instruct the sample stage 108 to vary the sample position of the sample according to a predetermined pattern. The controller 180 may instruct the sample stage 108 to vary the sample position in response to an information received, in particular an information received from the processing unit 170, in particular in response to the signal of the detectors 118, 119 at a particular position of the sample stage 108 and/or of the sample.

The controller 180 may receive information from the processing unit 170. In particular, the controller 180 may receive information on at least one beam spot parameter from the processing unit 170.

The charged particle beam system comprises one or more beam influencing elements 106. The one or more beam influencing elements 106 typically influence a shape of the charged particle beam 11 by inducing at least one of magnetic or electric fields interacting with the charged particle beam 11. The one or more beam influencing elements 106 can influence the beam spot, and particularly at least one beam spot parameter. In some embodiments, the at least one beam influencing element 106 comprises a multipole, exemplarily at least one of a dipole, a quadrupole, a hexapole, an octupole or a dodecapole. The one or more beam influencing element 106 may comprise a plurality of beam influencing elements 106. Typically, the one or more beam influencing element 106 comprises a single beam influencing element 106. The single beam influencing element 106 is typically configured to replicate an influence on the charged particle beam 11 of a plurality of beam influencing elements 106. Typically, a plurality of poles of a multipole may be interconnected to replicate the behavior of one of the plurality of beam influencing elements 106. Particularly, poles of a higher order beam influencing element 106 may be interconnected to replicate a lower order beam influencing element 106. Exemplarily, poles of an octupole may be interconnected to act similar to a dipole.

In typical embodiments, specific beam influencing elements 106 are configured to influence a specific beam spot parameter or beam aberration. In particular, typically, a beam shift may be corrected or induced by a dipole; an astigmatism may be corrected or induced by a quadrupole; a 3-fold astigmatism may be corrected or induced by a hexapole; and a 4-fold astigmatism may be corrected or induced by an octupole. Thus, in an idealized charged particle beam system 100, a variation of a configuration of a specific beam influencing element 106 only influences the associated beam spot parameter. However, in real charged particle beam systems 100 cross-talk between different orders of beam spot parameters typically exists. In particular, a change of a charged particle beam setting typically influences not only a beam spot parameter theoretically associated with said charged particle beam setting, but can influence beam spot parameters of different orders, particularly of lower orders. Exemplarily, when correcting an astigmatism using a quadrupole, an undesired beam shift may be introduced. Reaching a desired configuration of the charged particle beam systems can be cumbersome.

The charged particle beam 11 of the charged particle beam system 100 may be characterized by the beam spot of the charged particle beam 11, and particularly by at least one beam spot parameter. The at least one beam spot parameter typically characterizes a deviation of the beam spot from an ideal beam spot, in other words, a beam aberration. The at least one beam spot parameter can comprise at least one of a beam shift, an astigmatism, a 3-fold astigmatism, a 4-fold astigmatism or higher order beam aberrations.

In some embodiments, the charged particle beam system 100 comprises a beam analysis unit. The beam analysis unit can be part of the processing unit 170. In some embodiments, the beam analysis unit may form a separate unit or may be embedded in a cloud computing infrastructure. The beam analysis unit is typically configured to quantitatively determining the at least one beam spot parameter of the charged particle beam.

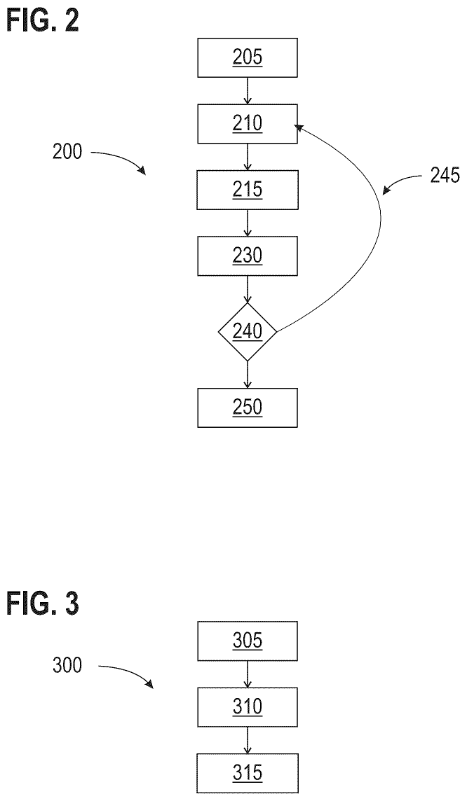

FIG. 2 schematically illustrates a method 200 of configuring a charged particle beam system comprising one or more beam influencing elements 106. Typically, the method 200 is computer-implemented, exemplarily using the controller of the charged particle beam system. The method 200 comprises providing 205 an initial configuration matrix of the charged particle system. Typically, a configuration matrix M relates to a plurality of charged particle beam settings to respective configurations of the one or more beam influencing elements. Exemplarily, a user or operator of the charged particle beam system may provide the charged particle beam system with a user instruction via an interface for receiving the user instruction. The controller of the charged particle beam system 100 may use the configuration matrix M to translate the user instruction into a change of settings of the one or more beam influencing elements.

Typically, each of the columns of the configuration matrix M comprises charged particle beam settings associated to a specific charged particle beam setting. Each of the rows of the configuration matrix M comprises configurations of single beam influencing elements, particularly currents or voltages applied to single beam influencing elements. Exemplarily, a column of the configuration matrix M may comprise charged particle beam settings associated to a beam shift in x-direction. Typically, the columns of the configuration matrix M are ordered along the dimensionality of the charged particle beam setting or the dimensionality of the aberration associated with the charged particle beam setting. For configuring the charge particle beam system 100, the configuration matrix M is typically multiplied with an excitation vector. For a charged particle beam system 100 with n adjustable currents or voltages, the configuration matrix M is typically an m×n matrix, with m being the number of beam influencing elements, and exemplarily is an n×n matrix.

An initial configuration matrix may be based upon at least one of a theoretical or simulated model of the charged particle beam system. In some embodiments, the initial configuration matrix may be based upon a configuration matrix of another charged particle beam system 100, particularly of a prototype charged particle beam system 100.

The initial configuration matrix may be employed as the configuration matrix M. In other words, the configuration matrix M is provided 210 from the initial configuration matrix. Providing 210 the configuration matrix M may particularly comprise loading the initial configuration matrix from a computer memory. In some embodiments, providing 210 the configuration matrix M may comprise selecting one of a plurality of initial configuration matrixes. Exemplarily, the memory may store a plurality of initial configuration matrixes representative of different configurations of the charged particle beam system and/or different past configuration matrixes.

The method 200 comprises determining 215 a correlation matrix C corresponding to the configuration matrix M of the charged particle beam system. The charged particle beam system typically comprises a beam analysis unit for quantitatively determining the at least one beam spot parameter of the charged particle beam. The correlation matrix C describes an influence of configurations of the one or more beam influencing elements on at least one beam spot parameter of a charged particle beam of the charged particle beam system. In particular, the correlation matrix C quantitatively describes changes in at least one beam spot parameter in response to changes in configurations of the one or more beam influencing elements. Determining the correlation matrix C corresponding to the configuration matrix M can comprise varying the one or more beam influencing elements, particularly independent from each other, and recording a change in at least one beam spot parameter. In the correlation matrix C, for a, particularly predetermined, variation of a configuration one of the one or more beam influencing elements, a quantitative change in a plurality of beam spot parameters is recorded in a column. Typically, the one or more beam influencing elements are varied independently and/or subsequently to determine a quantitative change in the plurality of beam spot parameters for the plurality of beam influencing elements. In the correlation matrix C, in each column the quantitative change in the plurality of beam spot parameters is provided for a single beam influencing element 106. The correlation matrix C may provide information on a degree of coupling of different alignment degrees of freedom.

Typically, the correlation matrix C is an n×n matrix, with n being the alignment degree of freedom, in other words the number of adjustable beam influencing elements. Typically, the correlation matrix C is an orthogonalizable matrix, particularly with the determinant of the correlation matrix C not being 0.

Typically, determining 215 the correlation matrix C comprises analyzing a charged particle beam cross section. Analyzing the charged particle beam cross section particularly comprises determining at least one beam spot parameter of the charged particle beam. Typically, the at least one beam spot parameter comprises an absolute and/or quantitative value, particularly determined along a metric. Analyzing the charged particle beam cross section can comprise varying a configuration of one of the one or more beam influencing elements from a first configuration, exemplarily from a first current configuration and/or voltage configuration, to a second configuration, exemplarily to a second current configuration and/or voltage configuration, and analyzing a change in the charged particle beam cross section between the first configuration and the second configuration. Typically, analyzing the charged particle beam cross section comprises recording at least one image of the charged particle beam and particularly a processing of the at least one image to obtain the charged particle beam cross section. Processing of the at least one image may comprise at least one of an image registration process, an aberration analysis, an image sharpness analysis, a numerical aperture analysis or a beam convergence analysis.

Typically, determining 215 the correlation matrix C comprises providing a quantitative indication of the at least one beam spot parameter of the charged particle beam. Typically, the quantitative indication comprises at least one numerical value, particularly determined along a metric. Providing a quantitative indication of the at least one beam spot parameter typically comprises an aberration analysis. Exemplarily, a beam shift, an astigmatism, a 3-fold astigmatism or a 4-fold astigmatism may be determined. Providing a quantitative indication of the at least one beam spot parameter can comprise providing a metric for assigning a quantitative value or score to at least one beam spot parameter.

In some embodiments, analyzing the charged particle beam cross section and providing a quantitative indication of the at least one beam spot parameter comprises applying a trained machine learning model on the charged particle beam cross section. In particular, the at least one image of the charged particle beam, and particularly an image of the beam spot, may be provided to the trained machine learning model.

The trained machine learning model is typically based upon a training process employing input data and a corresponding plurality of one or more beam spot parameter coefficients. The input data typically comprises a plurality of charged particle beam cross sections for a plurality of defocus settings of the charged particle beam.

In particular, the trained machine learning model may be generated by obtaining input data associated with a plurality of beam spot information, exemplarily a plurality of images of the beam spot, for a plurality of defocus settings; obtaining a plurality of beam spot parameters, particularly aberration coefficients, associated with corresponding input data of the input data; providing a training data set including the plurality of beam spot parameters and the corresponding input data; and producing or generating the trained machine learning model by machine learning from the training data set.

In some embodiments, the input data may be obtained from a simulation. In particular, charged particle beam cross sections may be simulated based upon a plurality of configurations of the one or more beam influencing elements. Simulating input data may advantageously allow to reduce a time-and cost-effort for obtaining the input data and may allow to obtain input data representative of rare charged particle beam system configurations, exemplarily rare misalignments, and/or rare configurations of the one or more beam influencing elements. In some embodiments, the input data may be obtained from prototype charged particle beam systems that may be operated under varying configurations of the one or more beam influencing elements to obtain associated beam spot parameters. In some embodiments, the input data may be obtained from field charged particle beam systems. Obtaining measured data of real systems may advantageously allow to obtain input data representative of common misalignments as well as misalignment not foreseen during development. Further, measured data of real systems may be influenced by circumstances not covered by simulation models. In some embodiments, the input data may be obtained from a combination of simulated and measured charged particle beam cross sections.

In some embodiments, analyzing the charged particle beam cross section and providing a quantitative indication of the at least one beam spot parameter comprises simulating a simulated charged beam cross section based on at least one estimated beam spot parameter. The at least one estimated beam spot parameter may be provided and/or selected by the user or operator of the charged particle beam system. The at least one estimated beam spot parameter is typically varied in an iterative process until a difference metric between the charged particle beam cross section and the simulated charged particle beam cross section is below a predefined simulation threshold. Once the difference metric between the charged particle beam cross section and the simulated charged particle beam cross section is below a predefined simulation threshold, the at least one estimated beam spot parameter, upon which the simulated charged particle beam cross section is based, is accepted as a real beam spot parameter.

In some embodiments, analyzing the charged particle beam cross section and providing the quantitative indication of the at least one beam spot parameter of the charged particle beam may be performed on the controller of the charged particle beam system. In some embodiments, analyzing a charged particle beam cross section and providing a quantitative indication of the at least one beam spot parameter of the charged particle beam may be performed in a cloud computing infrastructure. Employing a cloud computing infrastructure may advantageously allow to employ more computing power and to reduce a computing power and/or a memory of the controller of the charged particle beam system.

The method 200 comprises replacing 230 the configuration matrix M based upon the correlation matrix C. Typically, replacing 230 the configuration matrix M based upon the correlation matrix C comprises calculating an inverted correlation matrix C⁻¹ by inverting the correlation matrix C; and replacing the configuration matrix M by multiplying the configuration matrix M with the inverted correlation matrix C⁻¹.

The correlation matrix C may be inverted using the controller of the charged particle beam system. In some embodiments, the correlation matrix C may be inverted using a cloud computing infrastructure. The inverted correlation matrix C⁻¹ multiplied with the correlation matrix C yields an identity matrix. Typically, the inverted correlation matrix C⁻¹ is determined from the correlation matrix C using a numerical inversion algorithm, exemplarily a LU decomposition algorithm, a Gauss-Jordan elimination, a Strassen algorithm, a Coppersmith-Winograd algorithm or an optimized Coppersmith-Winograd-like algorithm. A matrix may be considered as the inverted correlation matrix C⁻¹ if the matrix fulfills an inversion criterium.

In some embodiments, the configuration matrix M may be replaced 230 by right multiplying the configuration matrix M with the inverted correlation matrix C⁻¹. Typically, the configuration matrix M and the correlation matrix C have the same size.

The method 200 comprises comparing 240 the correlation matrix C corresponding to the configuration matrix M with a diagonalization criterium. The diagonalization criterium particularly comprises a deviation metric of the correlation matrix C from the identity matrix. Exemplarily, the diagonalization criterium may comprise a trace and/or a determinant of the correlation matrix C. The diagonalization criterium may comprise a deviation of the determinant of the correlation matrix C from 1. The diagonalization criterium may be adjustable by the user or operator of the charged particle beam system, exemplarily via the interface.

For a correlation matrix C fulfilling 250 the diagonalization criterium, the corresponding configuration matrix M may be implemented as a final configuration matrix M_{final}. The charged particle beam system may be aligned using the final configuration matrix M_{final}.

For a correlation matrix C not fulfilling the diagonalization criterium, a diagonalization iteration 245 of determining the correlation matrix C corresponding to the configuration matrix M, and replacing the configuration matrix M, is repeated until the correlation matrix C corresponding to the configuration matrix M fulfills the diagonalization criterium. Typically, the diagonalization iteration 245 is repeated at most 8 times, at most 5 times; exemplarily 2 or 3 times. In some embodiments, the repeating the diagonalization iteration 245 may comprise a single iteration. In other words, the correlation matrix C corresponding to the initial configuration matrix of the charged particle beam system may already fulfill the diagonalization criterium.

In FIG. 3, a method 300 of setting one or more beam influencing elements is shown. Setting one or more beam influencing elements particularly comprises setting a current configuration and/or a voltage configuration for the one or more beam influencing elements. Setting one or more beam influencing elements may comprise providing set points to the controller of the charged particle beam system. The method 300 comprises receiving 305 charged particle beam system settings. The charged particle beam settings may particularly be received 305 from an interface configured to receive a user or operator input. Particularly, the user or operator may indicate a desired charged particle beam setting or a desired change in the charged particle beam settings. The user or operator may indicate a desired change in a beam spot parameter, exemplarily in the beam shift, in the astigmatism, in the 3-fold astigmatism or in the 4-fold astigmatism. In some embodiments, quantitative charged particle beam system settings can be provided by the user or operator.

In some embodiments, the interface comprises a human-machine interface. In particular, the interface may comprise a control panel, exemplarily comprising one or more knobs. In some embodiments, the interface may comprise a data interface. The charged particle beam system may receive 305 charged particle beam system settings from a computer system or a cloud computing infrastructure.

The method 300 of setting one or more beam influencing elements comprises providing 310 a configuration matrix M. The configuration matrix M may be provided 310 from a memory, in particular from a memory of the charged particle beam system, exemplarily from a memory of the controller. In some embodiments, the configuration matrix M may be set during an initial alignment of the charged particle beam system. In some embodiments, the configuration matrix M may be determined regularly, in particular in regular maintenance intervals or after maintenance events. In some embodiments, the charge particle beam system may comprise a plurality of configuration matrixes M, exemplarily for different use scenarios. The charge particle beam system may comprise a maintenance configuration matrix different from a standard configuration matrix M. In some embodiments, the user or operator may select a configuration matrix optimized for a specific use case.

The configuration matrix M is typically configured to reduce crosstalk between different orders of charged particle beam system settings of the charged particle beam. Particularly, the configuration matrix M is typically configured to reduce crosstalk between higher orders and lower orders of charged particle beam system settings of the charged particle beam system.

In typical embodiments, the configuration matrix M is generated by one of the embodiments described herein. Particularly, a correlation matrix C corresponding to the configuration matrix M fulfills the diagonalization criterium. A configuration matrix M may be considered as being configured to reduce crosstalk between different orders of charged particle beam system settings if the correlation matrix C corresponding to the configuration matrix M fulfills the diagonalization criterium.

The method 300 of setting one or more beam influencing elements comprises setting 315 one or more beam influencing elements of a charged particle beam system according to the configuration matrix and the charged particle beam system settings. In particular, the charged particle beam system settings may be provided as a vector with vector entries representing desired charged particle beam settings, particularly for specific beam spot parameters. To obtain configurations of the one or more beam influencing elements, the configuration matrix M can be multiplied with the vector.

Typically, translating a user instruction received via the interface into a change of settings of the one or more beam influencing elements using the configuration matrix M associated with the modified correlation matrix C fulfilling the diagonalization criterium is performed by the controller of the charged particle beam system. In some embodiments, the user instruction may be translated by an external computer or a cloud computing infrastructure.

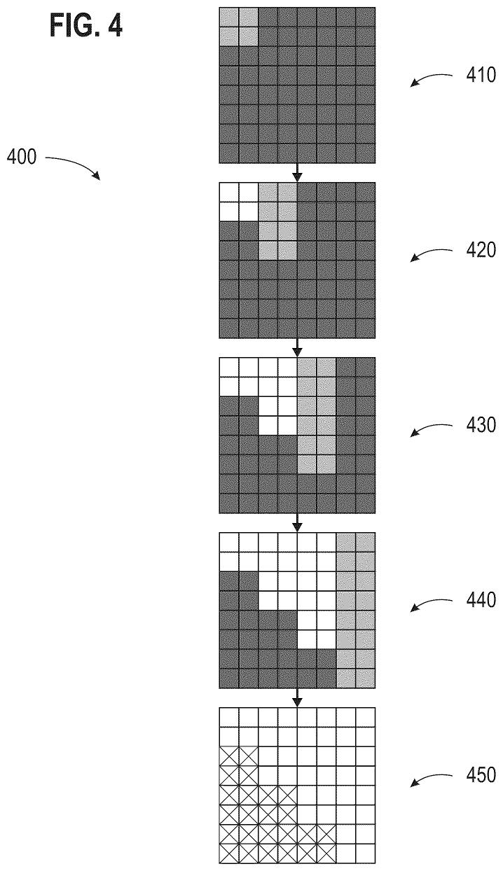

In FIG. 4, an order iteration 400 is schematically illustrated. In particular, FIG. 4 shows an iterative diagonalization of at least one of the configuration matrix M or the correlation matrix C. The order iteration 400 can advantageously allow to incorporate higher order configurations of the one or more beam influencing elements and higher order beam spot parameters of the charged particle beam. The matrixes schematically depicted in FIG. 4 are 8×8 matrixes. Typically, for each dimension of the configurations of the one or more beam influencing elements and the at least one beam spot parameter, a configuration and/or a beam spot parameter is provided or determined in x-direction and in y-direction, with the x-direction being perpendicular to the y-direction.

Typically, lower order excitations do not substantially influence higher order beam spot parameters. Exemplarily, a 3-fold astigmatism is not substantially affected by configurations of a dipole or of a quadrupole. In typical embodiments, matrix entries relating lower order excitations to higher order beam spot parameters, may be set to zero. Assuming that matrix entries relating lower order excitations to higher order beam spot parameters are negligibly small advantageously facilitates determining the correlation matrix for each order of the configuration matrix. Particularly, a more stable convergence of the diagonalization iteration can be obtained.

The order iteration 400 comprises diagonalizing matrix entries associated with first order 410 configurations and beam spot parameters. Particularly, configurations of a dipole in x-direction and of a dipole in y-direction may be related to a beam shift in x-direction and a beam shift in y-direction. In some embodiments, a diagonalization iteration, as described herein, is performed to diagonalize the matrix entries associated with first order 410 configurations and beam spot parameters.

A second order diagonalization 420 may be performed, typically subsequent to the first order 410 diagonalization. The second order diagonalization 420 comprises diagonalizing matrix entries associated with second order 420 configurations and beam spot parameters. Particularly, configurations of a quadrupole in x-direction and of a quadrupole in y-direction may be related to a beam shift in x-direction, a beam shift in y-direction, an astigmatism in x-direction and an astigmatism in y-direction. In some embodiments, a diagonalization iteration, as described herein, is performed to diagonalize the matrix entries associated with second order 420 configurations and beam spot parameters.

A third order diagonalization 430 may be performed, typically subsequent to the second order 420 diagonalization. The third order diagonalization 430 comprises diagonalizing matrix entries associated with third order 430 configurations and beam spot parameters. Particularly, configurations of an hexapole in x-direction and of an hexapole in y-direction may be related to a beam shift in x-direction, a beam shift in y-direction, an astigmatism in x-direction, an astigmatism in y-direction, a 3-fold astigmatism in x-direction and a 3-fold astigmatism in y-direction. In some embodiments, a diagonalization iteration, as described herein, is performed to diagonalize the matrix entries associated with third order 430 configurations and beam spot parameters.

A fourth order diagonalization 440 may be performed, typically subsequent to the third order 430 diagonalization. The fourth order diagonalization 440 comprises diagonalizing matrix entries associated with fourth order 440 configurations and beam spot parameters. Particularly, configurations of an octupole in x-direction and of an octupole in y-direction may be related to a beam shift in x-direction, a beam shift in y-direction, an astigmatism in x-direction, an astigmatism in y-direction, a 3-fold astigmatism in x-direction, a 3-fold astigmatism in y-direction, a 4-fold astigmatism in x-direction and a 4-fold astigmatism in y-direction. In some embodiments, a diagonalization iteration, as described herein, is performed to diagonalize the matrix entries associated with fourth order 440 configurations and beam spot parameters.

For even higher order configurations and beam spot parameters, the order iteration 400 may be executed accordingly. Typically, at least subsequent to the order iteration, matrix entries of the correlation matrix C relating lower order excitations to higher order beam spot parameters are set 450 to zero or are not measured. In other words, matrix entries of the correlation matrix C below the main diagonal are typically set to zero. The main diagonal of the correlation matrix C typically comprises matrix entries relating configurations of the one or more beam influencing elements to beam spot parameters of the same order. The correlation matrix may be considered as an upper triangular matrix.

In some embodiments, the order iteration and the diagonalization iteration are nested one in another. In particular, for each order of the order iteration, a diagonalization iteration according to embodiments described herein may be performed.

Specifically, the following embodiments are described herein:
Embodiment 1: A method of configuring a charged particle beam system comprising one or more beam influencing elements, the method comprising: providing an initial configuration matrix of the charged particle beam system, the initial configuration matrix relating a plurality of charged particle beam system settings to respective configurations of the one or more beam influencing elements, and providing a configuration matrix M from the initial configuration matrix; determining a correlation matrix C corresponding to the configuration matrix M of the charged particle beam system, the correlation matrix C describing an influence of configurations of the one or more beam influencing elements on at least one beam spot parameter of a charged particle beam of the charged particle beam system; replacing the configuration matrix M based upon the correlation matrix C; and iteratively repeating a diagonalization iteration of determining the correlation matrix C corresponding to the configuration matrix M, and replacing the configuration matrix M, until the correlation matrix C corresponding to the configuration matrix M fulfills a diagonalization criterium.
Embodiment 2: The method of embodiment 1, wherein replacing the configuration matrix M based upon the correlation matrix C comprises: calculating an inverted correlation matrix C⁻¹ by inverting the correlation matrix C; and replacing the configuration matrix M by multiplying the configuration matrix M with the inverted correlation matrix C⁻¹.
Embodiment 3: The method of any of the preceding embodiments, wherein the configurations of the one or more beam influencing elements comprise at least one of a current configuration or a voltage configuration of at least one of a dipole, a quadrupole, a hexapole, an octupole or a dodecapole.
Embodiment 4: The method of any of the preceding embodiments, further comprising performing an order iteration by iteratively increasing an order of at least one of the configuration matrix M or the correlation matrix C to incorporate higher order configurations of the one or more beam influencing elements and higher order beam spot parameters of the charged particle beam.
Embodiment 5: The method of any of the preceding embodiments, wherein the at least one beam spot parameter of the charged particle beam comprises at least one of a beam shift, an astigmatism, a 3-fold astigmatism or a 4-fold astigmatism.
Embodiment 6: The method of any of the preceding embodiments, wherein determining the correlation matrix C comprises analyzing a charged particle beam cross section and providing a quantitative indication of the at least one beam spot parameter of the charged particle beam.
Embodiment 7: The method of embodiment 6, wherein analyzing the charged particle beam cross section and providing a quantitative indication of the at least one beam spot parameter comprises applying a trained machine learning model on the charged particle beam cross section.
Embodiment 8: The method of any of embodiments 6-7, wherein the trained machine learning model is based upon a training process employing input data and a corresponding plurality of one or more beam spot parameter coefficients; and the input data comprising a plurality of charged particle beam cross sections for a plurality of defocus settings of the charged particle beam.
Embodiment 9: The method of any of embodiments 6-8, wherein analyzing the charged particle beam cross section and providing a quantitative indication of the at least one beam spot parameter comprises simulating a simulated charged beam cross section based on at least one estimated beam spot parameter; and varying the at least one estimated beam spot parameter in an iterative process until a difference metric between the charged particle beam cross section and the simulated charged particle beam cross section is below a predefined simulation threshold.
Embodiment 10: The method of any of the preceding embodiments, wherein the correlation matrix C is an upper triangular matrix.
Embodiment 11: The method of any of the preceding embodiments, further comprising implementing the configuration matrix M corresponding to the correlation matrix C fulfilling the diagonalization criterium as a final configuration matrix M_{final}; and aligning the charged particle beam system using the final configuration matrix M_{final}.
Embodiment 12: A method of setting one or more beam influencing elements; the method comprising receiving charged particle beam system settings; providing a configuration matrix M; and setting one or more beam influencing elements of a charged particle beam system according to the configuration matrix M and the charged particle beam system settings; wherein the configuration matrix M is configured to reduce crosstalk between different orders of charged particle beam system settings of the charged particle beam system.
Embodiment 13: The method of embodiment 12, wherein the configuration matrix M is generated by the method of embodiments 1 to 11.
Embodiment 14: A charged particle beam system comprising one or more beam influencing elements and a controller, wherein the controller is configured to provide an initial configuration matrix of the charged particle beam system, the initial configuration matrix relating a plurality of charged particle beam system settings to respective configurations of the one or more beam influencing elements; and to provide a configuration matrix M from the initial configuration matrix; determine a correlation matrix C corresponding to the configuration matrix M of the charged particle beam system, the correlation matrix C describing an influence of configurations of the one or more beam influencing elements on at least one beam spot parameter of a charged particle beam of the charged particle beam system; replace the configuration matrix M based upon the correlation matrix C; and iteratively repeat a diagonalization iteration of determining the correlation matrix C corresponding to the configuration matrix M, and replacing the configuration matrix M, until the correlation matrix C corresponding to the configuration matrix M fulfills a diagonalization criterium.
Embodiment 15: The system of embodiment 14, wherein replacing the configuration matrix M based upon the correlation matrix C comprises calculating an inverted correlation matrix C⁻¹ by inverting the correlation matrix C; and replacing the configuration matrix M by multiplying the configuration matrix M with the inverted correlation matrix C⁻¹.
Embodiment 16: The method of any of embodiments 14 to 15, wherein the one or more beam influencing element comprises a dipole, a quadrupole, a hexapole, an octupole or a dodecapole.
Embodiment 17: The method of any of embodiments 14 to 16, wherein the controller is further configured to perform an order iteration by iteratively increasing an order of at least one of the configuration matrix M or the correlation matrix C to incorporate higher order configurations of the one or more beam influencing elements and higher order beam profile parameters of the charged particle beam.
Embodiment 18: The method of any of embodiments 14 to 17, wherein the at least one beam spot parameter of the charged particle beam comprises at least one of a beam shift, an astigmatism, a 3-fold astigmatism or a 4-fold astigmatism.
Embodiment 19: The method of any of embodiments 14 to 18, further comprising a beam analysis unit for quantitatively determining the at least one beam spot parameter of the charged particle beam.
Embodiment 20: The method of embodiments 19, wherein quantitatively determining the at least one beam spot parameter of the charged particle beam comprises applying a trained machine learning model.
Embodiment 21: The method of any of embodiments 19 to 20, wherein quantitatively determining the at least one beam spot parameter of the charged particle beam comprises simulating a simulated charged beam cross section based on at least one estimated beam spot parameter; and varying the at least one estimated beam spot parameter in an iterative process until a difference metric between the charged particle beam cross section and the simulated charged particle beam cross section is below a predefined simulation threshold.
Embodiment 22: The method of any of embodiments 14 to 21, further comprising an interface for receiving a user instruction, the user instruction relating to a change in the at least one beam spot parameter, wherein the controller is configured to translate the user instruction into a change of settings of the one or more beam influencing elements using the configuration matrix M associated with the correlation matrix C fulfilling the diagonalization criterium.

Embodiments of the present disclosure provide one or more of the following advantages. Alignment of the charged particle beam system may be facilitated and alignment downtimes may be shortened using a configuration matrix with a corresponding correlation matrix fulfilling a diagonalization criterium. The charged particle beam system may be configured using existing hardware. Using existing hardware, the resolution of the charged particle beam system may be improved, particularly by providing an improved method of setting the one or more beam influencing elements. The embodiments described herein are typically independent of a specific hardware implementation and may be applied to a plurality of different charged particle beam systems. More complex charged particle beam systems may be developed and operated employing the methods described herein, providing a better performance and improved specifications. A combination of quantitatively determining beam profile parameters and diagonalizing the correlation matrix allows to diagonalize higher order beam profile parameters with higher order beam influencing elements and may allow a coupling to further degrees of freedom, exemplarily to numerical aperture or coma effects.

While the foregoing is directed to embodiments, other and further embodiments may be devised without departing from the basic scope thereof, and the scope thereof is determined by the claims that follow.

What is claimed is:

1. A method of configuring a charged particle beam system comprising one or more beam influencing elements, the method comprising:
providing an initial configuration matrix of the charged particle beam system, the initial configuration matrix relating a plurality of charged particle beam system settings to respective configurations of the one or more beam influencing elements, and providing a configuration matrix M from the initial configuration matrix;
determining a correlation matrix C corresponding to the configuration matrix M of the charged particle beam system, the correlation matrix C describing an influence of configurations of the one or more beam influencing elements on at least one beam spot parameter of a charged particle beam of the charged particle beam system;
replacing the configuration matrix M based upon the correlation matrix C; and
iteratively repeating a diagonalization iteration of determining the correlation matrix C corresponding to the configuration matrix M, and replacing the configuration matrix M, until the correlation matrix C corresponding to the configuration matrix M fulfills a diagonalization criterium.

2. The method of claim 1, wherein replacing the configuration matrix M based upon the correlation matrix C comprises:
calculating an inverted correlation matrix C⁻¹ by inverting the correlation matrix C; and
replacing the configuration matrix M by multiplying the configuration matrix M with the inverted correlation matrix C⁻¹.

3. The method of claim 1, wherein the configurations of the one or more beam influencing elements comprise at least one of a current configuration or a voltage configuration of at least one of a dipole, a quadrupole, a hexapole, an octupole or a dodecapole.

4. The method of claim 1, further comprising performing an order iteration by iteratively increasing an order of at least one of the configuration matrix M or the correlation matrix C to incorporate higher order configurations of the one or more beam influencing elements and higher order beam spot parameters of the charged particle beam.

5. The method of claim 1, wherein the at least one beam spot parameter of the charged particle beam comprises at least one of a beam shift, an astigmatism, a 3-fold astigmatism or a 4-fold astigmatism.

6. The method of claim 1, wherein determining the correlation matrix C comprises analyzing a charged particle beam cross section and providing a quantitative indication of the at least one beam spot parameter of the charged particle beam.

7. The method of claim 6, wherein analyzing the charged particle beam cross section and providing a quantitative indication of the at least one beam spot parameter comprises applying a trained machine learning model on the charged particle beam cross section.

8. The method of claim 7, wherein:
the trained machine learning model is based upon a training process employing input data and a corresponding plurality of one or more beam spot parameter coefficients; and
the input data comprising a plurality of charged particle beam cross sections for a plurality of defocus settings of the charged particle beam.

9. The method of claim 6, wherein analyzing the charged particle beam cross section and providing a quantitative indication of the at least one beam spot parameter comprises:
simulating a simulated charged beam cross section based on at least one estimated beam spot parameter; and
varying the at least one estimated beam spot parameter in an iterative process until a difference metric between the charged particle beam cross section and the simulated charged particle beam cross section is below a predefined simulation threshold.

10. The method of claim 1, further comprising:
implementing the configuration matrix M corresponding to the correlation matrix C fulfilling the diagonalization criterium as a final configuration matrix M_{final}; and
aligning the charged particle beam system using the final configuration matrix M_{final}.

11. A method of setting one or more beam influencing elements; the method comprising:
receiving charged particle beam system settings;
providing a configuration matrix M; and
setting one or more beam influencing elements of a charged particle beam system according to the configuration matrix M and the charged particle beam system settings;
wherein the configuration matrix M is configured to reduce crosstalk between different orders of charged particle beam system settings of the charged particle beam system.

12. The method of claim 11, wherein the configuration matrix M is generated by:
providing an initial configuration matrix of the charged particle beam system, the initial configuration matrix relating a plurality of charged particle beam system settings to respective configurations of the one or more beam influencing elements, and providing a configuration matrix M from the initial configuration matrix;
determining a correlation matrix C corresponding to the configuration matrix M of the charged particle beam system, the correlation matrix C describing an influence of configurations of the one or more beam influencing elements on at least one beam spot parameter of a charged particle beam of the charged particle beam system;
replacing the configuration matrix M based upon the correlation matrix C; and
iteratively repeating a diagonalization iteration of determining the correlation matrix C corresponding to the configuration matrix M, and replacing the configuration matrix M, until the correlation matrix C corresponding to the configuration matrix M fulfills a diagonalization criterium.

13. A charged particle beam system comprising one or more beam influencing elements and a controller, wherein the controller is configured to:
provide an initial configuration matrix of the charged particle beam system, the initial configuration matrix relating a plurality of charged particle beam system settings to respective configurations of the one or more beam influencing elements; and to provide a configuration matrix M from the initial configuration matrix;
determine a correlation matrix C corresponding to the configuration matrix M of the charged particle beam system, the correlation matrix C describing an influence of configurations of the one or more beam influencing elements on at least one beam spot parameter of a charged particle beam of the charged particle beam system;
replace the configuration matrix M based upon the correlation matrix C; and
iteratively repeat a diagonalization iteration of determining the correlation matrix C corresponding to the configuration matrix M, and replacing the configuration matrix M, until the correlation matrix C corresponding to the configuration matrix M fulfills a diagonalization criterium.

14. The system of claim 13, wherein the controller is configured to replace the configuration matrix M based upon the correlation matrix C by:
calculating an inverted correlation matrix C⁻¹ by inverting the correlation matrix C; and
replacing the configuration matrix M by multiplying the configuration matrix M with the inverted correlation matrix C⁻¹.

15. The system of claim 13, wherein the controller is further configured to perform an order iteration by iteratively increasing an order of at least one of the configuration matrix M or the correlation matrix C to incorporate higher order configurations of the one or more beam influencing elements and higher order beam profile parameters of the charged particle beam.

16. The system of claim 13, wherein the at least one beam spot parameter of the charged particle beam comprises at least one of a beam shift, an astigmatism, a 3-fold astigmatism or a 4-fold astigmatism.

17. The system of claim 13, further comprising a beam analysis unit for quantitatively determining the at least one beam spot parameter of the charged particle beam.

18. The system of claim 17, wherein quantitatively determining the at least one beam spot parameter of the charged particle beam comprises applying a trained machine learning model.

19. The system of claim 17, wherein quantitatively determining the at least one beam spot parameter of the charged particle beam comprises
simulating a simulated charged beam cross section based on at least one estimated beam spot parameter; and
varying the at least one estimated beam spot parameter in an iterative process until a difference metric between the charged particle beam cross section and the simulated charged particle beam cross section is below a predefined simulation threshold.

20. The system of claim 13, further comprising an interface for receiving a user instruction, the user instruction relating to a change in the at least one beam spot parameter, wherein the controller is configured to translate the user instruction into a change of settings of the one or more beam influencing elements using the configuration matrix M associated with the correlation matrix C fulfilling the diagonalization criterium.
